(19) United States
(12) Patent Application Publication
(10) Pub. No.: US 2024/0067876 A1
(43) Pub. Date: Feb. 29, 2024

(54) Series of Alkali Metal Borophosphates Compounds, and Alkali Metal Borophosphates Nonlinear Optical Crystals as well as Preparation Method and Application thereof

(71) Applicant: TIANJIN UNIVERSITY OF TECHNOLOGY, Tianjin (CN)

(72) Inventors: Hongwei YU, Tianjin (CN); Haonan LIU, Tianjin (CN); Hongping WU, Tianjin (CN); Zhanggui HU, Tianjin (CN)

(21) Appl. No.: 17/957,307

(22) Filed: Sep. 30, 2022

(30) Foreign Application Priority Data
Aug. 26, 2022 (CN) 202211033912X

(51) Int. Cl. C09K 11/71; C01B 35/14

(52) U.S. Cl. CPC C09K 11/71; C01B 35/143

(57) ABSTRACT

The present invention relates to compounds and their nonlinear optical (NLO) crystals of A₃B₁₁P₂O₂₃ (A=K, Rb, Cs, NH₄), their producing method and uses thereof. The series of compounds have a chemical formula of A₃B₁₁P₂O₂₃ (A=K, Rb, Cs, NH₄), which are namely K₃B₁₁P₂O₂₃, Rb₃B₁₁P₂O₂₃, Cs₃B₁₁P₂O₂₃ and (NH₄)₃B₁₁P₂O₂₃. The series of NLO crystals having the chemical formula of A₃B₁₁P₂O₂₃ (A=K, Rb, Cs, NH₄), belong to rhombohedral crystal system, and have a space group of R3, crystal cell parameters of a=b=10.016(5)-12.591(5) Å, c=12.105(6)-14.905(6) Å, Z=3. A₃B₁₁P₂O₂₃ (A=K, Rb, Cs, NH₄) compounds were prepared by a solid-state reaction method or a hydrothermal method, and A₃B₁₁P₂O₂₃ (A=K, Rb, Cs, NH₄) NLO crystals were prepared by a high-temperature solid-state reaction method, a hydrothermal method, or a solution method. T They meet the requirements for the frequency conversion of UV wavelength lasers and could be used to prepare nonlinear optical devices.

### CROSS REFERENCE TO RELATED APPLICATION

The present invention relates to alkali metal borophosphates compounds with a chemical formula of A₃B₁₁P₂O₂₃ (A=K, Rb, Cs, NH₄), alkali metal borophosphate nonlinear optical crystals, a preparation method of the crystals and a nonlinear optical apparatus manufactured from the crystals.

### BACKGROUND OF THE INVENTION

Deep-ultraviolet (DUV) coherent lights with wavelengths between 200 and 150 nm are of increasing importance owing to their potential applications in semiconductor photolithography, laser micromachining, modern scientific instruments. For solid-state lasers, the best way to obtain the DUV coherent lights is through the cascaded frequency conversion technology of nonlinear optical (NLO) crystals. However, for an applicable DUV NLO crystal, it must satisfy the following harsh structural and properties' requirements, including i) the non-centrosymmetric (NCS) structures; ii) large second-order NLO coefficients (dᵢⱼ), at least comparable to the d₃₆ of KDP; iii) high transparency in the DUV region with the UV cut-off wavelength as short as possible; iv) a moderate birefringence (Δn=0.05-0.10) to satisfy the phase-matching condition of second-harmonic generation (SHG) in the UV or DUV region; and v) ease of growth, non-toxic, chemical stability, and good mechanical properties. However, since some of the above properties are conflicted, e.g., the materials with large band gaps often exhibit small SHG responses and birefringence, designing and synthesizing a DUV NLO crystal is still a great challenge. Borophosphates with asymmetric [BO₄] and [PO₄] tetrahedra as basic building blocks usually have large band gaps, and are widely regarded as candidates for exploring UV or DUV optical crystals. Notably, BPO₄ has a strong second-harmonic response (2×KDP), and its UV transmittance range extends to about 130 nm. However, its small birefringence of 0.005@1064 nm makes conventional phase matching impossible, and the crystal cannot be used as a UV NLO crystal. However, π-conjugated [BO₃] groups with excellent optical anisotropy are beneficial to improve the birefringence of the material. Therefore, designing and synthesizing borophosphates with [BO₃], [BO₄] and [PO₄] groups are an effective way to design DUV NLO materials.

### SUMMARY OF THE INVENTION

The first objective of the present invention is to provide alkali metal borophosphates compounds with a chemical formula of A₃B₁₁P₂O₂₃ (A=K, Rb, Cs, NH₄). The series of single crystals belong to rhombohedral crystal system, and have a space group of R3, crystal cell parameters of a=b=10.016(5)-12.591(5) Å, c=12.105(6)-14.905(6) Å, Z=3. The polycrystalline powder was prepared through a solid-state reaction method or a hydrothermal method.

Another objective of the present invention is to provide alkali metal borophosphate nonlinear optical crystals and a preparation method thereof. The crystals have a chemical formula of A₃B₁₁P₂O₂₃ (A=K, Rb, Cs, NH₄), and belong to rhombohedral crystal system, as well as have a space group of R3, crystal cell parameters of a=b=10.016(5)-12.591(5) Å, c=12.105(6)-14.905(6) Å, Z=3. The preparation methods are high-temperature solid-state reaction method, hydrothermal method, and solution method.

Another objective of the present invention is to provide the use of alkali metal borophosphates nonlinear optical apparatus in nonlinear optical devices such as second harmonic generators, up and down frequency converters, optical parametric oscillations, laser frequency conversion devices, and laser communications.

The present invention adopts the following technical solution:

The alkali metal borophosphates provided by the present invention have a chemical formula of A₃B₁₁P₂O₂₃ (A=K, Rb, Cs, NH₄). The series of single crystals belong to rhombohedral crystal system, and have a space group of R3, crystal cell parameters of a=b=10.016(5)-12.591(5) Å, c=12.105(6)-14.905(6) Å, Z=3. The preparation processes adopt a high-temperature solid-state reaction method, a hydrothermal method or a solution method based on the following steps:

The high-temperature solid-state reaction method is used to prepare nonlinear optical crystals A₃B₁₁P₂O₂₃, wherein A=K, Rb, Cs, NH₄, comprising the following steps: A mixture of a A-containing compound (A=K, Rb, Cs, NH₄), a boron-containing compound, a phosphorus-containing compound was thoroughly ground, and the mixture was preheated to 350-800° C., held at this temperature for a period of time, with several intermediate grindings to get the A₃B₁₁P₂O₂₃ (A=K, Rb, Cs, NH₄) single phase, wherein element A=K, Rb, Cs, NH₄ in the A-containing compound, elemental boron in the boron-containing compound, and elemental phosphorus in the phosphorus-containing compound are in a molar ratio of 2.5-3.5:10.5-11.5:1.5-2.5.

The hydrothermal method is used to prepare nonlinear optical crystals A₃B₁₁P₂O₂₃, wherein A=K, Rb, Cs, NH₄, comprising the following steps: a. A mixture of a A-containing compound (A=K, Rb, Cs, NH₄), a boron-containing compound, a phosphorus-containing compound was combined with deionized water (0.1-50 mL) or mineralizer 0.1-50 g, in which element A=K, Rb, Cs, NH₄ in the A-containing compound, elemental boron in the boron-containing compound, and elemental phosphorus in the phosphorus-containing compound are in a molar ratio of 1-4:10-12:1-3;
b. The mixture was loaded into the Teflon-lined autoclave and subsequently sealed;
c. The autoclave was heated to 120-330° C., held at this temperature for a period of time, and then cooled to room temperature;
d. Open the autoclave and filter the solution containing crystals to obtain transparent alkali metal borophosphates nonlinear optical crystals.

The solution method is used to prepare A₃B₁₁P₂O₂₃, wherein A=K, Rb, Cs, NH₄ nonlinear optical crystals, comprising the following steps: A mixture of a A-containing compound (A=K, Rb, Cs, NH₄), a boron-containing compound, a phosphorus-containing compound, and deionized water (0.1-400 mL) was placed in a beaker and stirred until dissolved completely. Then put the beaker on the heating table and heat it to 25-400° C. After a period of time, the series of alkali metal borophosphates nonlinear optical crystals are obtained. In order to further grow them, the seed crystals of the series of nonlinear optical crystals were suspended in solution with fine platinum wires. In order to reduce the evaporation of water, the beaker is covered with a layer of polyethylene plate and pierced with dozens of millimeter sized holes. After a period of time, take out the centimeter size alkali metal borophosphates nonlinear optical crystals from the solution.

The alkali metal borophosphates compounds provided by the present invention have a chemical formula of A₃B₁₁P₂O₂₃ (A=K, Rb, Cs, NH₄), which are namely K₃B₁₁P₂O₂₃, Rb₃B₁₁P₂O₂₃, Cs₃B₁₁P₂O₂₃, (NH₄)₃B₁₁P₂O₂₃, and the formula weights are 666.15, 805.26, 947.57, and 602.97, respectively. The series of alkali metal borophosphates compounds can be prepared by a high-temperature solid-state reaction method, a hydrothermal method, or a solution method based on the following chemical reaction formulas:
1) 3A₂CO₃ (A=K, Rb, Cs, NH₄)+22H₃BO₃+4NH₄H₂PO₄→2A₃B₁₁P₂O₂₃ (A=K, Rb, Cs, NH₄)+39H₂O↑+3CO₂↑+4NH₃↑
2) 3AOH (A=K, Rb, Cs, NH₄)+11H₃BO₃+P₂O₅→A₃B₁₁P₂O₂₃ (A=K, Rb, Cs, NH₄)+18H₂O↑
3) 3A₂CO₃ (A=K, Rb, Cs, NH₄)+22H₃BO₃+2P₂O₅→2A₃B₁₁P₂O₂₃ (A=K, Rb, Cs, NH₄)+33H₂O↑+3CO₂↑
4) 3A₂O (A=K, Rb, Cs, NH₄)+22H₃BO₃+2P₂O₅→2A₃B₁₁P₂O₂₃ (A=K, Rb, Cs, NH₄)+33H₂O↑
5) 3AF (A=K, Rb, Cs, NH₄)+11H₃BO₃+2NH₄H₂PO₄→A₃B₁₁P₂O₂₃ (A=K, Rb, Cs, NH₄)+18 H₂O↑+3HF↑+2NH₃↑
6) 3A₂CO₃ (A=K, Rb, Cs, NH₄)+11B₂O₃+4NH₄H₂PO₄→2A₃B₁₁P₂O₂₃ (A=K, Rb, Cs, NH₄)+6H₂O↑+3CO₂↑+4NH₃↑
7) 3A₂CO₃ (A=K, Rb, Cs, NH₄)+11B₂O₃+2P₂O₅→2A₃B₁₁P₂O₂₃ (A=K, Rb, Cs, NH₄)+3CO₂↑
8) 3AH₂PO₄ (A=K, Rb, Cs, NH₄)+5.5B₂O₃→A₃B₁₁P₂O₂₃ (A=K, Rb, Cs, NH₄)+1.5H₂O↑+H₃PO₄
9) 3A₂HPO₄ (A=K, Rb, Cs, NH₄)+11B₂O₃+0.5P₂O₅→2A₃B₁₁P₂O₂₃ (A=K, Rb, Cs, NH₄)+1.5H₂O↑
10) 6AOH (A=K, Rb, Cs, NH₄)+11B₂O₃+2P₂O₅→2A₃B₁₁P₂O₂₃ (A=K, Rb, Cs, NH₄)+3H₂O↑
11) 12AH₂PO₄ (A=K, Rb, Cs, NH₄)+22H₃B₂O₃+2P₂O₅→4A₃B₁₁P₂O₂₃ (A=K, Rb, Cs, NH₄)+33H₂↑+8H₃PO₄
12) 6ACl (A=K, Rb, Cs, NH₄)+11B₂O₃+4NH₄H₂PO₄→2A₃B₁₁P₂O₂₃ (A=K, Rb, Cs, NH₄)+6HCl↑+4NH₃↑+3H₂O↑
13) 6ACl (A=K, Rb, Cs, NH₄)+22H₃BO₃+2P₂O₅→2A₃B₁₁P₂O₂₃ (A=K, Rb, Cs, NH₄)+6HCl↑+30H₂O↑

The alkali metal borophosphates nonlinear optical crystals provided by the present invention are characterized in that the crystals have a chemical formula of A₃B₁₁P₂O₂₃ (A=K, Rb, Cs, NH₄), and belong to rhombohedral crystal system, as well as have a space group of R3, crystal cell parameters of a=b=10.016(5)-12.591(5) Å, c=12.105(6)-14.905(6) Å, Z=3.

The alkali metal borophosphates nonlinear optical crystals provided by the present invention adopt a high-temperature solid-state reaction method, a hydrothermal method or a solution method based on the following specific operation steps:

The high-temperature solid-state reaction method is used to prepare A₃B₁₁P₂O₂₃, wherein A=K, Rb, Cs, NH₄ nonlinear optical crystals, comprising the following steps:
a. Uniformly mixed the compound alkali metal borophosphates single-phase polycrystalline powder with the fluxing agents, and heated it to a temperature of 350-800° C., and kept it at a constant temperature for a period of time to obtain a mixed melt, and then cooled to 300-750° C., in which the molar ratios of the compound alkali metal borophosphates single-phase polycrystalline powder to the fluxing agents are 1:0-20;

Or directly heat the mixture of a A-containing compound (A=K, Rb, Cs, NH₄), a boron-containing compound, and a phosphorus-containing compound or the mixture of a A-containing compound (A=K, Rb, Cs, NH₄), a boron-containing compound, a phosphorus-containing compound and the fluxing agents to 350-800° C., and held at this temperature for a period of time to obtain a mixed melt. And then cooled to a temperature of 300-750° C., in which the molar ratios of a A-containing compound (A=K, Rb, Cs, NH₄), a boron-containing compound and a phosphorus-containing compound to the fluxing agents are 2.5-3.5:10.5-11.5:1.5-2.5:0-20;

The fluxing agents mainly include at least one or more of alkali metal salts, i.e., alkali metal carbonates, alkali metal nitrates, alkali metal sulfates, alkali metal oxalates, alkali metal borates, alkali metal phosphates, alkali metal halides, alkali metal fluoroborates, alkali metal metaborates, and alkali metal oxides, alkali metal hydroxides, and monohydrogen phosphates, dihydrogen phosphates, boron oxide, boric acid, phosphoric acid, lead oxide, lead fluoride, molybdenum oxide, bismuth oxide.

The compound alkali metal borophosphates single-phase polycrystalline powder are prepared by a solid-state method, including the following steps: mixing a A-containing compound (A=K, Rb, Cs, NH₄), a boron-containing compound and a phosphorus-containing compound by a solid-state method to obtain the compound alkali metal borophosphates. The element A=K, Rb, Cs, NH₄ in the A-containing compound, the element boron in the boron-containing compound, and the element phosphorus in the phosphorus-containing compound are in a molar ratio of 2.5-3.5:10.5-11.5:1.5-2.5, and the raw materials of the A-containing compound (A=K, Rb, Cs, NH₄), the boron-containing compound and the phosphorus-containing compound are mixed uniformly. After grinding, the mixture was preheated to remove moisture and gas, and then cool to room temperature.

Further, the mixture was gradually heated to 350-800° C., held at this temperature for a period of time. The alkali metal borophosphates compounds single-phase polycrystalline powder are obtained.
b. Preparation of alkali metal borophosphates seed crystals: the mixture obtained in step a. is slowly cooled to room temperature, and spontaneously crystallized to obtain alkali metal borophosphate seeds;
c. A seed crystal of A₃B₁₁P₂O₂₃ (A=K, Rb, Cs, NH₄) was attached with Pt wire to a Pt rod. After being preheated above the solution surface, the seed was introduced into the melt, and held at this temperature for a period of time, the temperature of the furnace was lowered quickly to the initial crystallization temperature.
d. Continue to cool down slowly, and rotate the seed crystal rod to grow the crystal. When the growth was completed, the crystal was drawn out of the melt surface, and the temperature dropped to room temperature, and then obtain the alkali metal borophosphates nonlinear optical crystals.

The hydrothermal method is used to prepare A₃B₁₁P₂O₂₃, wherein A=K, Rb, Cs, NH₄ nonlinear optical crystals, comprising the following steps:
a. A mixture of a A-containing compound (A=K, Rb, Cs, NH₄), a boron-containing compound, a phosphorus-containing compound was combined with deionized water (0.1-50 mL) or mineralizer 0.1-50 g, in which element A=K, Rb, Cs, NH₄ in the A-containing compound, elemental boron in the boron-containing compound, and elemental phosphorus in the phosphorus-containing compound are in a molar ratio of 2-4:10-12:1-3;
b. The mixture was loaded into Teflon-lined autoclave and subsequently sealed;
c. The autoclave was heated to 120-330° C., held at this temperature for a period of time, and then cooled to room temperature;
d. Open the autoclave and filter the solution containing crystals to obtain a transparent alkali metal borophosphates nonlinear optical crystals.

The solution method is used to prepare A₃B₁₁P₂O₂₃, wherein A=K, Rb, Cs, NH₄ nonlinear optical crystals, comprising the following steps:

A mixture of a A-containing compound (A=K, Rb, Cs, NH₄), a boron-containing compound, a phosphorus-containing compound, and deionized water (0.1-400 mL) was placed in a beaker and stirred until dissolved completely. Then put the beaker on the heating table and heat it to 25-400° C. After a period of time, a series of alkali metal borophosphates nonlinear optical crystals are obtained. In order to further grow them, the seed crystals of the series of crystals were suspended in solution with fine platinum wires. In order to reduce the evaporation of water, the beaker is covered with a layer of polyethylene plate and pierced with dozens of millimeter sized holes. After a period of time, take out a centimeter size alkali metal borophosphates nonlinear optical crystals from the solution.

The alkali metal borophosphates crystals have the advantages of high purity, easy crystal growth, transparent and no package, fast growth speed, low cost and easy to obtain large-size crystals; the obtained crystals have the advantages of wide light transmission band, high hardness, good mechanical properties, not easy to break and deliquescence, and easy to process and preserve. The nonlinear optical device made of the series of alkali metal borophosphates nonlinear optical crystals obtained by the method of the invention in manufacturing a nonlinear optical device comprising means for generating at least one output radiation with a frequency different from that of the incident electromagnetic radiation after passing at least one beam of incident electromagnetic radiation through at least one nonlinear optical crystal, wherein the nonlinear optical crystal is A₃B₁₁P₂O₂₃, in which A=K, Rb, Cs, NH₄, and the molecular formula are K₃B₁₁P₂O₂₃, Rb₃B₁₁P₂O₂₃, Cs₃B₁₁P₂O₂₃, and (NH₄)₃B₁₁P₂O₂₃, respectively.

### BRIEF DESCRIPTION OF THE FIGURES

FIG. 1 is an X-ray powder diffraction pattern of a compound Rb₃B₁₁P₂O₂₃ of the present invention;

FIG. 2 is an X-ray powder diffraction pattern of a compound Cs₃B₁₁P₂O₂₃ of the present invention;

FIG. 3 is a structural diagram of a A₃B₁₁P₂O₂₃ (A=K, Rb, Cs, NH₄) crystal of the present invention;

FIG. 4 is a working schematic diagram of a nonlinear optical apparatus manufactured from A₃B₁₁P₂O₂₃ (A=K, Rb, Cs, NH₄) crystal of the present invention, where 1 is the laser generator, 2 is the incident laser beam, 3 is post-treated and optically fabricated A₃B₁₁P₂O₂₃ (A=K, Rb, Cs, NH₄) NLO devices, 4 is a output beam and 5 is a filter.

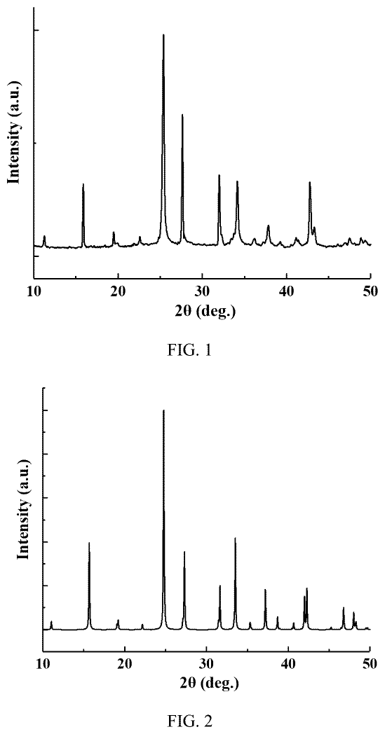

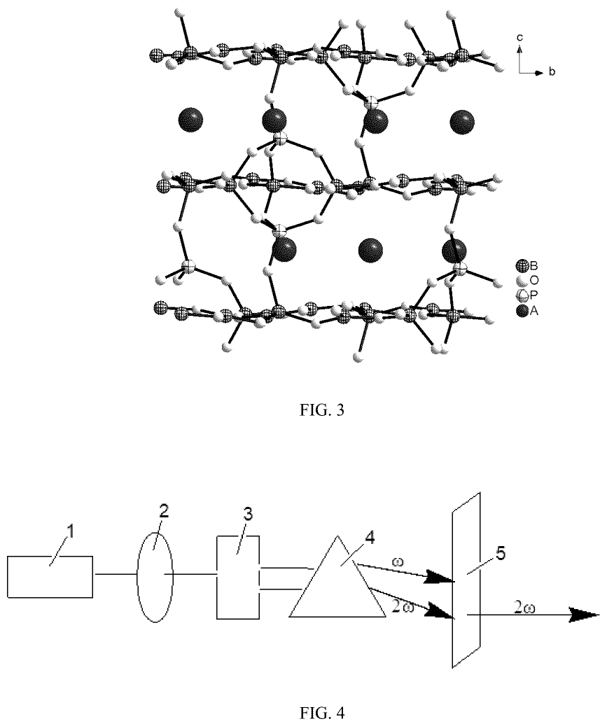

### DETAILED DESCRIPTION OF THE PREFERRED EMBODIMENTS

The present invention is described above through specific embodiments, but the invention is not limited to these embodiments.

### Embodiment 1

A₃B₁₁P₂O₂₃ (A=K, Rb, Cs, NH₄) polycrystalline powder was prepared according to a reaction formula: 3A₂CO₃ (A=K, Rb, Cs, NH₄)+22H₃BO₃+4NH₄H₂PO₄→2A₃B₁₁P₂O₂₃ (A=K, Rb, Cs, NH₄)+39H₂O↑+3CO₂↑+4NH₃↑ as follows:

Reagents were weighed according to stoichiometric proportion and were put in a mortar, and then mixed and ground carefully. The mixture was put in a lidless corundum crucible of size of (100 mm×100 mm. The said crucible was put into a muffle furnace, heated to 350° C. slowly and held at this temperature for 24 hours. After being cooled down, the loose and porous sample was taken out of the crucible and was once again mixed thoroughly, ground and put back to the crucible and compacted. The mixture was heated at 550° C. for 24 h and cooled to room temperature. The sample was then taken out and ground thoroughly, and the mixture was put back to the crucible and heated at 550° C. for 48 h. The product was analyzed by the powder X-ray diffraction of the product, where the X-ray diffraction pattern was consistent with a theoretical X-ray diffraction pattern of A₃B₁₁P₂O₂₃ (A=K, Rb, Cs, NH₄) analyzed by a single-crystal structure.

Then, the single-phase polycrystalline powder was put into a (80 mm×80 mm lidless platinum crucible which was placed in the center of a vertical, programmable temperature furnace, was heated at 850° C. until the melt became transparent and clear, held at this temperature for 15 h, and then quickly cooled to the initial crystallization temperature (650° C.). Then, a platinum wire was promptly dipped into the solution. The temperature was decreased at a rate of 0.5° C./h, then the platinum wire was pulled out of the solution, and allowed to cool to room temperature at a rate of 10° C./h.

Thus, a few colorless, transparent plate crystals crystallized on the platinum wire. The obtained crystals could be used as seeds. A seed crystal of A₃B₁₁P₂O₂₃ (A=K, Rb, Cs, NH₄) was attached with Pt wire to a Pt rod and then suspended on solution at 600° C. for a quarter. The seed crystal was kept at this temperature in solution for half an hour while rotating at a rate of 10 rpm. The temperature of the furnace was first lowered quickly to 550° C. and then lowered at a rate of 2° C./day. After the growth of crystal ended, the crystal was lifted out of liquid surface. The temperature of the crystal was then lowered to room temperature at a rate of 10° C./h. As a result, transparent A₃B₁₁P₂O₂₃ (A=K, Rb, Cs, NH₄) crystal with a size of 56 mm×40 mm×30 mm was obtained.

### Embodiment 2

A₃B₁₁P₂O₂₃ (A=K, Rb, Cs, NH₄) polycrystalline powder was prepared according to a reaction formula: 3AOH (A=K, Rb, Cs, NH₄)+11H₃BO₃+P₂O₅→A₃B₁₁P₂O₂₃ (A=K, Rb, Cs, NH₄)+18H₂O↑ as follows:

Reagents were weighed according to stoichiometric proportion, preparation of A₃B₁₁P₂O₂₃ (A=K, Rb, Cs, NH₄) crystal by fluxing agent method: AOH (A=K, Rb, Cs, NH₄)—P₂O₅ as the fluxing agent system, the said reagents are used as the solute with the molar ratio of solute:fluxing agent=1:4, the molar ratio of AOH (A=K, Rb, Cs, NH₄)/P₂O₅ was selected at 3/5. Then, mixed the said reagents with fluxing agent and put into a Φ 80 mm×80 mm lidless platinum crucible which was placed in the center of a vertical, programmable temperature furnace, was heated at 800° C., held at this temperature for 60 h, and then quickly cooled to the initial crystallization temperature (750° C.).

The temperature was decreased to room temperature at a rate of 1.5° C./h to obtain the seeds.

A seed crystal of A₃B₁₁P₂O₂₃ (A=K, Rb, Cs, NH₄) was attached with Pt wire to a Pt rod and then suspended on solution at 700° C. for ten minutes. The seed crystal was kept at this temperature in solution for half an hour while rotating at a rate of 10 rpm. The temperature of the furnace was first lowered quickly to 600° C. and then lowered at a rate of 1° C./day. After the growth of crystal ended, the crystal was lifted out of liquid surface. The temperature of the crystal was then lowered to room temperature at a rate of 20° C./h. As a result, transparent A₃B₁₁P₂O₂₃ (A=K, Rb, Cs, NH₄) crystal with a size of 36 mm×22 mm×15 mm was obtained.

### Embodiment 3

A₃B₁₁P₂O₂₃ (A=K, Rb, Cs, NH₄) polycrystalline powder was prepared according to a reaction formula: 3A₂CO₃ (A=K, Rb, Cs, NH₄)+22H₃BO₃+2P₂O₅→2A₃B₁₁P₂O₂₃ (A=K, Rb, Cs, NH₄)+33H₂O↑+3CO₂↑ as follows:

The said polycrystalline A₃B₁₁P₂O₂₃ (A=K, Rb, Cs, NH₄) is used as the solute with the molar ratio of solute:fluxing agent (H₃BO₃—P₂O₅)=1:3. Then, mixed homogeneously and put into a Φ 80 mm×80 mm lidless platinum crucible which was placed in the center of a vertical, programmable temperature furnace, was heated at 350° C. until the melt became transparent and clear, held at this temperature for 60 h, and then quickly cooled to the initial crystallization temperature (330° C.).

The temperature was decreased to room temperature at a rate of 3.5° C./h to obtain the seeds.

A seed crystal of A₃B₁₁P₂O₂₃ (A=K, Rb, Cs, NH₄) was attached with Pt wire to a Pt rod and then suspended on solution for 15 minutes. The seed crystal was kept at this temperature in solution for twenty minutes while rotating at a rate of 5 rpm. The temperature of the furnace was first lowered quickly to 315° C. and then lowered at a rate of 3° C./day.

After the growth of crystal ended, the crystal was lifted out of liquid surface. The temperature of the crystal was then lowered to room temperature at a rate of 1° C./h. As a result, transparent A₃B₁₁P₂O₂₃ (A=K, Rb, Cs, NH₄) crystal with a size of 25 mm×24 mm×10 mm was obtained.

### Embodiment 4

A₃B₁₁P₂O₂₃ (A=K, Rb, Cs, NH₄) polycrystalline powder was prepared according to a reaction formula: 3A₂O (A=K, Rb, Cs, NH₄)+22H₃BO₃+2P₂O₅→2A₃B₁₁P₂O₂₃ (A=K, Rb, Cs, NH₄)+33H₂O↑ as follows:
a. Reagents were weighed according to stoichiometric proportion, and loaded into a 21 mL Teflon-lined autoclave, further added 3 mL deionized water to obtain the mixed liquid.
b. The mixture was loaded into Teflon-lined autoclave and subsequently sealed;
c. The autoclave was heated to 120° C. at a rate of 20° C./h, held at this temperature for 5 days, and then cooled to room temperature at a rate of 4° C./h;
d. Open the autoclave and filter the solution containing crystals to obtain a transparent alkali metal borophosphates compounds.

### Embodiment 5

A₃B₁₁P₂O₂₃ (A=K, Rb, Cs, NH₄) polycrystalline powder was prepared according to a reaction formula: 3AF (A=K, Rb, Cs, NH₄)+11H₃BO₃+2NH₄H₂PO₄→A₃B₁₁P₂O₂₃ (A=K, Rb, Cs, NH₄)+18 H₂O↑+3HF↑+2NH₃↑ as follows:
a. Reagents were weighed according to stoichiometric proportion, and loaded into a 150 mL Teflon-lined autoclave, further added 50 mL deionized water to obtain the mixed liquid.
b. The mixture was loaded into Teflon-lined autoclave and subsequently sealed;
c. The autoclave was heated to 330° C. at a rate of 10° C./h, held at this temperature for 10 days, and then cooled to room temperature at a rate of 3° C./h;
d. Open the autoclave and filter the solution containing crystals to obtain a transparent alkali metal borophosphates compounds.

### Embodiment 6

A₃B₁₁P₂O₂₃ (A=K, Rb, Cs, NH₄) polycrystalline powder was prepared according to a reaction formula: 3A₂CO₃ (A=K, Rb, Cs, NH₄)+11B₂O₃+4NH₄H₂PO₄→2A₃B₁₁P₂O₂₃ (A=K, Rb, Cs, NH₄)+6H₂O↑+3CO₂↑+4NH₃↑ as follows:

Reagents were weighed according to stoichiometric proportion, and then the mixture was placed in a beaker (10 mL), further add 0.1 mL deionized water into the beaker and stirred until dissolved completely. Then put the beaker on the heating table and heat it to 25° C. After 2 days, the series of alkali metal borophosphates nonlinear optical crystals are obtained. In order to further grow them, the seed crystals of the series of crystals were suspended in solution with fine platinum wires. In order to reduce the evaporation of water, the beaker is covered with a layer of polyethylene plate and pierced with dozens of millimeter sized holes. After 3 weeks, take out a centimeter size alkali metal borophosphates nonlinear optical crystals from the solution.

### Embodiment 7

A₃B₁₁P₂O₂₃ (A=K, Rb, Cs, NH₄) polycrystalline powder was prepared according to a reaction formula: 3A₂CO₃ (A=K, Rb, Cs, NH₄)+11B₂O₃+2P₂O₅→2A₃B₁₁P₂O₂₃ (A=K, Rb, Cs, NH₄)+3CO₂↑ as follows:

Reagents were weighed according to stoichiometric proportion, and then the mixture was placed in a beaker (1000 mL), further add 400 mL deionized water into the beaker and stirred until dissolved completely. Then put the beaker on the heating table and heat it to 400° C. After 7 days, the series of alkali metal borophosphates nonlinear optical crystals are obtained. In order to further grow them, the seed crystals of the series of crystals were suspended in solution with fine platinum wires. In order to reduce the evaporation of water, the beaker is covered with a layer of polyethylene plate and pierced with dozens of millimeter sized holes. After 5 weeks, take out a centimeter size alkali metal borophosphate nonlinear optical crystal from the solution.

### Embodiment 8

A₃B₁₁P₂O₂₃ (A=K, Rb, Cs, NH₄) polycrystalline powder was prepared according to a reaction formula: 3AH₂PO₄ (A=K, Rb, Cs, NH₄)+5.5B₂O₃→A₃B₁₁P₂O₂₃ (A=K, Rb, Cs, NH₄)+1.5H₂O↑+H₃PO₄ as follows:

Reagents were weighed according to stoichiometric proportion, preparation of A₃B₁₁P₂O₂₃ (A=K, Rb, Cs, NH₄) crystal by fluxing agent method: AOH (A=K, Rb, Cs, NH₄)—PbO as the fluxing agent system, the said reagents are used as the solute with the molar ratio of solute:fluxing agent=4:7, the molar ratio of AOH (A=K, Rb, Cs, NH₄)/PbO was selected at 1/6. Then, mixed the said reagents with fluxing agent and put into a Φ80 mm×80 mm lidless platinum crucible which was placed in the center of a vertical, programmable temperature furnace, was heated at 350° C., held at this temperature for 60 h, and then quickly cooled to the initial crystallization temperature (330° C.).

The temperature was decreased to room temperature at a rate of 3.5° C./h to obtain the seeds.

A seed crystal of A₃B₁₁P₂O₂₃ (A=K, Rb, Cs, NH₄) was attached with Pt wire to a Pt rod and then suspended on solution at 330° C. for 15 minutes. The seed crystal was kept at this temperature in solution for half an hour while rotating at a rate of 10 rpm. The temperature of the furnace was first lowered quickly to 315° C. and then lowered at a rate of 3° C./day. After the growth of crystal ended, the crystal was lifted out of liquid surface. The temperature of the crystal was then lowered to room temperature at a rate of 1° C./h. As a result, transparent A₃B₁₁P₂O₂₃ (A=K, Rb, Cs, NH₄) crystal with a size of 25 mm×24 mm×10 mm was obtained.

### Embodiment 9

A₃B₁₁P₂O₂₃ (A=K, Rb, Cs, NH₄) polycrystalline powder was prepared according to a reaction formula: 3A₂HPO₄ (A=K, Rb, Cs)+11B₂O₃+0.5P₂O₅→2A₃B₁₁P₂O₂₃ (A=K, Rb, Cs, NH₄)+1.5H₂O↑ as follows:

Reagents were weighed according to stoichiometric proportion, preparation of A₃B₁₁P₂O₂₃ (A=K, Rb, Cs, NH₄) crystal by fluxing agent method: A₂CO₃ (A=K, Rb, Cs, NH₄)—H₃BO₃—NH₄H₂PO₄ as the fluxing agent system, the said reagents are used as the solute with the molar ratio of solute:fluxing agent=5:2, the molar ratio of A₂CO₃ (A=K, Rb, Cs, NH₄ NH₄)/H₃BO₃/NH₄H₂PO₄ was selected at 5/16/16. Then, mixed the said reagents with fluxing agent and put into a (P 80 mm×80 mm lidless platinum crucible which was placed in the center of a vertical, programmable temperature furnace, was heated at 550° C., held at this temperature for 60 h, and then quickly cooled to the initial crystallization temperature (530° C.).

The temperature was decreased to room temperature at a rate of 3.5° C./h to obtain the seeds.

A seed crystal of A₃B₁₁P₂O₂₃ (A=K, Rb, Cs, NH₄) was attached with Pt wire to a Pt rod and then suspended on solution at 530° C. for 15 minutes. The seed crystal was kept at this temperature in solution for half an hour while rotating at a rate of 10 rpm. The temperature of the furnace was first lowered quickly to 515° C. and then lowered at a rate of 3° C./day. After the growth of crystal ended, the crystal was lifted out of liquid surface. The temperature of the crystal was then lowered to room temperature at a rate of 1° C./h. As a result, transparent A₃B₁₁P₂O₂₃ (A=K, Rb, Cs, NH₄) crystal with a size of 25 mm×24 mm×10 mm was obtained.

### Embodiment 10

A₃B₁₁P₂O₂₃ (A=K, Rb, Cs, NH₄) polycrystalline powder was prepared according to a reaction formula: 6AOH (A=K, Rb, Cs, NH₄)+11B₂O₃+2P₂O₅→2A₃B₁₁P₂O₂₃ (A=K, Rb, Cs, NH₄)+3H₂O↑ as follows:

Reagents were weighed according to stoichiometric proportion, preparation of A₃B₁₁P₂O₂₃ (A=K, Rb, Cs, NH₄) crystal by fluxing agent method: ABF₄-MoO₃ as the fluxing agent system, the said reagents are used as the solute with the molar ratio of solute:fluxing agent=9:3, the molar ratio of ABF₄/MoO₃ was selected at 4/7. Then, mixed the said reagents with fluxing agent and put into a Φ 80 mm×80 mm lidless platinum crucible which was placed in the center of a vertical, programmable temperature furnace, was heated at 450° C., held at this temperature for 60 h, and then quickly cooled to the initial crystallization temperature (400° C.).

The temperature was decreased to room temperature at a rate of 3.5° C./h to obtain the seeds.

A seed crystal of A₃B₁₁P₂O₂₃ (A=K, Rb, Cs, NH₄) was attached with Pt wire to a Pt rod and then suspended on solution at 405° C. for 15 minutes. The seed crystal was kept at this temperature in solution for half an hour while rotating at a rate of 10 rpm. The temperature of the furnace was first lowered quickly to 400° C. and then lowered at a rate of 3° C./day. After the growth of crystal ended, the crystal was lifted out of liquid surface. The temperature of the crystal was then lowered to room temperature at a rate of 1° C./h. As a result, transparent A₃B₁₁P₂O₂₃ (A=K, Rb, Cs, NH₄) crystal with a size of 25 mm×24 mm×10 mm was obtained.

### Embodiment 11

A₃B₁₁P₂O₂₃ (A=K, Rb, Cs, NH₄) polycrystalline powder was prepared according to a reaction formula: 12AH₂PO₄ (A=K, Rb, Cs, NH₄)+22H₃B₂O₃+2P₂O₅→4A₃B₁₁P₂O₂₃ (A=K, Rb, Cs, NH₄)+33H₂↑+8H₃PO₄ as follows:
a. Reagents were weighed according to stoichiometric proportion, and loaded into a 100 mL Teflon-lined autoclave, further added 50 g H₃BO₃ to obtain the mixed liquid.
b. The mixture was loaded into Teflon-lined autoclave and subsequently sealed;
c. The autoclave was heated to 180° C. at a rate of 20° C./h, held at this temperature for 10 days, and then cooled to room temperature at a rate of 4° C./h;
d. Open the autoclave and filter the solution containing crystals to obtain a transparent alkali metal borophosphates compounds.

### Embodiment 12

A₃B₁₁P₂O₂₃ (A=K, Rb, Cs, NH₄) polycrystalline powder was prepared according to a reaction formula: 6ACl (A=K, Rb, Cs, NH₄)+11B₂O₃+4NH₄H₂PO₄→2A₃B₁₁P₂O₂₃ (A=K, Rb, Cs, NH₄)+6HCl↑+4NH₃↑+3H₂O↑ as follows:
a. Reagents were weighed according to stoichiometric proportion, and loaded into a 21 mL Teflon-lined autoclave, further added 0.1 g H₃BO₃ to obtain the mixed liquid.
b. The mixture was loaded into Teflon-lined autoclave and subsequently sealed;
c. The autoclave was heated to 160° C. at a rate of 10° C./h, held at this temperature for 11 days, and then cooled to room temperature at a rate of 4° C./h;
d. Open the autoclave and filter the solution containing crystals to obtain a transparent alkali metal borophosphates compounds.

### Embodiment 13

A₃B₁₁P₂O₂₃ (A=K, Rb, Cs, NH₄) polycrystalline powder was prepared according to a reaction formula: 6ACl (A=K, Rb, Cs, NH₄)+22H₃BO₃+2P₂O₅→2A₃B₁₁P₂O₂₃ (A=K, Rb, Cs, NH₄)+6HCl↑+30H₂O↑ as follows:

Reagents were weighed according to stoichiometric proportion, and then the mixture was placed in a beaker (10 mL), further add 0.1 mL deionized water into the beaker and stirred until dissolved completely. Then put the beaker on the heating table and heat it to 400° C. After 7 days, the series of alkali metal borophosphates nonlinear optical crystals are obtained. In order to further grow them, the seed crystals of the series of crystals were suspended in solution with fine platinum wires. In order to reduce the evaporation of water, the beaker is covered with a layer of polyethylene plate and pierced with dozens of millimeter sized holes. After 5 weeks, take out a centimeter size alkali metal borophosphate nonlinear optical crystal from the solution.

### Embodiment 14

Any K₃B₁₁P₂O₂₃, Rb₃B₁₁P₂O₂₃, Cs₃B₁₁P₂O₂₃, and (NH₄)₃B₁₁P₂O₂₃ nonlinear optical crystals obtained according to embodiments 1 to 13 were mounted on the position of 3 as shown in FIG. 4; a Q-switched Nd: YAG laser device was taken as a light source with an incident wavelength of 1064 nm at the room temperature came into K₃B₁₁P₂O₂₃, Rb₃B₁₁P₂O₂₃, Cs₃B₁₁P₂O₂₃, and (NH₄)₃B₁₁P₂O₂₃ single crystal 3 to generate frequency-doubled laser with a wavelength of 532 nm; and an outgoing beam 4 contained infrared lights with wavelengths of 1064 nm and 532 nm, and frequency-doubled laser with a wavelength of 532 nm was obtained after the light was filtered by a light filter 5.

### Embodiment 15

Any K₃B₁₁P₂O₂₃, Rb₃B₁₁P₂O₂₃, Cs₃B₁₁P₂O₂₃, and (NH₄)₃B₁₁P₂O₂₃ nonlinear optical crystals obtained according to embodiments 1 to 13 were mounted on the position of 3 as shown in FIG. 4; a Q-switched Nd: YAG laser device was taken as a light source with an incident wavelength of 532 nm at the room temperature came into K₃B₁₁P₂O₂₃, Rb₃B₁₁P₂O₂₃, Cs₃B₁₁P₂O₂₃, and (NH₄)₃B₁₁P₂O₂₃ single crystal 3 to generate frequency-doubled laser with a wavelength of 266 nm; and an outgoing beam 4 contained infrared lights with wavelengths of 532 nm and 266 nm, and frequency-doubled laser with a wavelength of 266 nm was obtained after the light was filtered by a light filter 5.

### Embodiment 16

Any K₃B₁₁P₂O₂₃, Rb₃B₁₁P₂O₂₃, Cs₃B₁₁P₂O₂₃, and (NH₄)₃B₁₁P₂O₂₃ nonlinear optical crystals obtained according to embodiments 1 to 13 were subjected to directional cutting and polishing processing to form a single crystal device. A 1064 nm Nd: YAG Q-switched laser source was used as a pump source to generate a laser output with a wavelength shorter than 266 nm.

What is claimed is:

1. A series of alkali metal borophosphates compounds, having a chemical formula of A₃B₁₁P₂O₂₃ (A=K, Rb, Cs, NH₄), i.e. K₃B₁₁P₂O₂₃, Rb₃B₁₁P₂O₂₃, Cs₃B₁₁P₂O₂₃, and (NH₄)₃B₁₁P₂O₂₃, in which the molecular weights are 666.15, 805.26, 947.57 and 602.97, respectively.

2. A method for synthesizing the compounds as claimed in claim 1, the series of alkali metal borophosphates compounds were synthesized by conventional solid-state reaction methods, or a hydrothermal method.

3. The synthesizing method for the series of alkali metal borophosphates compounds as claimed in claim 2, comprising the following steps:
the solid-state reaction method is used to prepare A₃B₁₁P₂O₂₃, wherein A=K, Rb, Cs, NH₄ compounds, comprising the following steps: A mixture of a A-containing compound (A=K, Rb, Cs, NH₄), a boron-containing compound, a phosphorus-containing compound was thoroughly ground. Then, the mixture was put into a muffle furnace for calcination, with several intermediate grindings to get the A₃B₁₁P₂O₂₃ (A=K, Rb, Cs, NH₄) single phase polycrystalline powder, wherein the element A=K, Rb, Cs, NH₄ in the A-containing compounds, the element boron in the boron-containing compounds, and the element phosphorus in the phosphorus-containing compounds are in a molar ratio of 2.5-3.5:10.5-11.5:1.5-2.5;
the hydrothermal method is used to prepare A₃B₁₁P₂O₂₃, wherein A=K, Rb, Cs, NH₄ compounds, comprising the following steps: A mixture of a A-containing compound (A=K, Rb, Cs, NH₄), a boron-containing compound, a phosphorus-containing compound was combined with deionized water (0.1-50 mL) or mineralizer 0.1-50 g, wherein element A=K, Rb, Cs, NH₄ in the A-containing compound, elemental boron in the boron-containing compound, and elemental phosphorus in the phosphorus-containing compound are in a molar ratio of 1-4:10-12:1-3; The mixture was loaded into Teflon-lined autoclave and subsequently sealed; The autoclave was heated, and then cooled to room temperature; Finally, filter the solution containing crystals to obtain the transparent alkali metal borophosphates compounds;
the A-containing compounds (A=K, Rb, Cs, NH₄) include at least one of AOH, A₂O and alkali metal salt; alkali metal salt includes at least one of AF, ACl, ABr, ANO₃, A₂C₂O₄, A₂CO₃, AHCO₃, A₂SO₄, wherein A=K, Rb, Cs, NH₄;
the boron containing compounds include at least one of B₂O₃, H₃BO₃ and boron salt; the boron salt includes at least one of ABO₂, ABO₃, A₃BO₃, A₂B₄O₇, wherein A=K, Rb, Cs, NH₄;
the phosphorus containing compounds include at least one of P₂O₅, H₃PO₄ and phosphorus salt; the phosphorus salt includes at least one of AH₂PO₄, A₂HPO₄, A₃PO₄, A₂H₂P₂O₇, A₄P₂O₇ wherein A=K, Rb, Cs, NH₄.

4. The alkali metal borophosphates nonlinear optical crystals having a chemical formula of A₃B₁₁P₂O₂₃ (A=K, Rb, Cs, NH₄), i.e. K₃B₁₁P₂O₂₃, Rb₃B₁₁P₂O₂₃, Cs₃B₁₁P₂O₂₃, and (NH₄)₃B₁₁P₂O₂₃, respectively, which belong to rhombohedral crystal system, and have a space group of R3 with unit-cell parameters a=b=10.016(5)-12.591(5) Å, c=12.105(6)-14.905(6) Å, Z=3.

5. A method for synthesizing the alkali metal nonlinear optical crystals as claimed in claim 4, the series of alkali metal borophosphates nonlinear optical crystals were synthesized by a high-temperature solid-state reaction method, a hydrothermal method, or a solution method.

6. The growth method for the series of alkali metal borophosphates nonlinear optical crystals as claimed in claim 5, based on the following operation steps:
the high-temperature solid-state reaction method is used to prepare A₃B₁₁P₂O₂₃, wherein A=K, Rb, Cs, NH₄ compounds, comprising the following steps: A₃B₁₁P₂O₂₃ (A=K, Rb, Cs, NH₄) compounds or a mixture of the A₃B₁₁P₂O₂₃ (A=K, Rb, Cs, NH₄) compounds with fluxing agent is heated to obtain a mixed melt. Or directly heat the mixture of the A-containing compound (A=K, Rb, Cs, NH₄), boron-containing compound and phosphorus-containing compound or the mixture of A-containing compound (A=K, Rb, Cs, NH₄), boron-containing compound, phosphorus-containing compound and fluxing agents to obtain a mixed melt. The crucible of the liquid is placed in the crystal growth furnace to cool down the temperature, and then the seed rod is lifted out of the liquid surface before the melt solidifies to obtain the seed crystal; the seed crystal is fixed on the seed rod, and the seed crystal is brought down to the liquid surface of the mixed melt or in the mixed melt for melting back to the saturation temperature; cooling or constant temperature growth. Finally, alkali metal borophosphates A₃B₁₁P₂O₂₃ (A=K, Rb, Cs, NH₄) nonlinear optical crystals were prepared;
the hydrothermal method is used to prepare A₃B₁₁P₂O₂₃, wherein A=K, Rb, Cs, NH₄ compounds, comprising the following steps: A₃B₁₁P₂O₂₃ (A=K, Rb, Cs, NH₄) compounds or a mixture of the A₃B₁₁P₂O₂₃ (A=K, Rb, Cs, NH₄) compounds with mineralizer; Or directly mixing the A-containing compound (A=K, Rb, Cs, NH₄), boron-containing compound and phosphorus-containing compound or the mixture of A-containing compound (A=K, Rb, Cs, NH₄), boron-containing compound, phosphorus-containing compound and mineralizer to obtain a mixed melt. The mixture was combined with deionized water, and loaded into Teflon-lined autoclave; The autoclave was heated, and then cooled to room temperature; Finally, filter the solution containing crystals to obtain the transparent alkali metal borophosphates A₃B₁₁P₂O₂₃ (A=K, Rb, Cs, NH₄) nonlinear optical crystals;
the solution method is used to prepare A₃B₁₁P₂O₂₃, wherein A=K, Rb, Cs, NH₄ compounds, comprising the following steps: A₃B₁₁P₂O₂₃ (A=K, Rb, Cs, NH₄) compounds or a mixture of the A₃B₁₁P₂O₂₃ (A=K, Rb, Cs, NH₄) compounds with cosolvent; Or directly mixing the A-containing compound (A=K, Rb, Cs, NH₄), boron-containing compound and phosphorus-containing compound or the mixture of A-containing compound (A=K, Rb, Cs, NH₄), boron-containing compound, phosphorus-containing compound and cosolvent to obtain a mixed melt. Then, the mixture was dissolved in deionized water and placed in a beaker stirred until dissolved completely. Then put the beaker on the heating table to heat for a period of time, the series of alkali metal borophosphates nonlinear optical crystals are obtained. In order to further grow them, the seed crystals of the series of crystals were suspended in solution with fine platinum wires. In order to reduce the evaporation of water, the beaker is covered with a layer of polyethylene plate and pierced with dozens of millimeter sized holes. After a period of time, take out a centimeter size alkali metal borophosphates A₃B₁₁P₂O₂₃ (A=K, Rb, Cs, NH₄) nonlinear optical crystals from the solution.

7. The crystal growth method according to claim 6, based on the following specific operation steps:
the high-temperature solid-state reaction method is used to prepare A₃B₁₁P₂O₂₃, wherein A=K, Rb, Cs, NH₄ nonlinear optical crystals. The series of alkali metal borophosphates compounds and the fluxing agent are in a ratio of 1:0-20; or a molar ratio of a A-containing compound (A=K, Rb, Cs, NH₄), a boron-containing compound, a phosphorus-containing compound and a fluxing agent is 2.5-3.5:10.5-11.5:1.5-2.5:0-20; The fluxing agents mainly include at least one or more of alkali metal salts, i.e., alkali metal carbonates, alkali metal nitrates, alkali metal sulfates, alkali metal oxalates, alkali metal borates, alkali metal phosphates, alkali metal halides, alkali metal fluoroborates, alkali metal metaborates, and alkali metal oxides, alkali metal hydroxides, and monohydrogen phosphates, dihydrogen phosphates, boron oxide, boric acid, phosphoric acid, lead oxide, lead fluoride, molybdenum oxide, bismuth oxide;
the hydrothermal method is used to prepare A₃B₁₁P₂O₂₃, wherein A=K, Rb, Cs, NH₄ nonlinear optical crystals. The series of alkali metal borophosphates compounds and the mineralizer are in a ratio of 1:0-10; or a molar ratio of a A-containing compound (A=K, Rb, Cs, NH₄), a boron-containing compound, a phosphorus-containing compound and a fluxing agent is 2-4:10-12:1-3:0-10; the mineralizer include at least one or more of AOH, A₂O, AF, ACl, ABr, ABF₄, A₃PO₄, A₃BO₃, ANO₃, A₂C₂O₄ A₂CO₃, AHCO₃, A₂SO₄, A₂HPO₄, AH₂PO₄, B₂O₃, wherein A=K, Rb, Cs, NH₄;
the solution method is used to prepare A₃B₁₁P₂O₂₃, wherein A=K, Rb, Cs, NH₄ nonlinear optical crystals. The series of alkali metal borophosphates compounds and the cosolvent are in a ratio of 1:0-30; or a molar ratio of a A-containing compound (A=K, Rb, Cs, NH₄), a boron-containing compound, a phosphorus-containing compound and a fluxing agent is 2.5-3.5:10.5-11.5:1.5-2.5:0-30; Cosolvents are self-cosolvents.

8. The use as claimed in claim 4, wherein said nonlinear optical crystals, A₃B₁₁P₂O₂₃ (A=K, Rb, Cs, NH₄) can be used as frequency converting apparatus, which generates a second, third, fourth or fifth harmonic of a 1064-nm Nd:YAG laser.

9. The use as claimed in claim 4, wherein said nonlinear optical crystals, A₃B₁₁P₂O₂₃ (A=K, Rb, Cs, NH₄) can be used in the preparation of multi-band frequency doubling devices or optics.

10. The use as claimed in claim 4, wherein said nonlinear optical crystals can be used as the second harmonic generator, the upper and lower frequency converters, optical parametric oscillator from infrared to ultraviolet.
